(19) United States
(12) Patent Application Publication
(10) Pub. No.: US 2025/0188606 A1
(43) Pub. Date: Jun. 12, 2025

(54) SUBSTRATE PROCESSING APPARATUS, SUBSTRATE PROCESSING METHOD, METHOD OF MANUFACTURING SEMICONDUCTOR DEVICE AND NON-TRANSITORY COMPUTER-READABLE RECORDING MEDIUM

(71) Applicant: Kokusai Electric Corporation, Tokyo (JP)

(72) Inventor: Yusaku OKAJIMA, Toyama-shi (JP)

(73) Assignee: Kokusai Electric Corporation, Tokyo (JP)

(21) Appl. No.: 19/060,323

(22) Filed: Feb. 21, 2025

Related U.S. Application Data
(63) Continuation of application No. PCT/JP2022/031771, filed on Aug. 23, 2022.

(51) Int. Cl. C23C 16/44; C23C 16/455; C23C 16/458; C23C 16/52; H01L 21/02

(52) U.S. Cl. CPC C23C 16/4412; C23C 16/45561; C23C 16/4584; C23C 16/52; H01L 21/02282

(57) ABSTRACT

It is possible to improve a uniformity of a substrate processing. There is provided a technique that includes: a process chamber in which a substrate is processed; a process gas supplier capable of supplying a process gas to the process chamber; a heater capable of heating the process chamber; a heat insulating chamber constituting a heat insulating region provided below the process chamber; an inert gas supplier capable of supplying an inert gas to the heat insulating chamber from thereunder; a first exhauster provided with a first exhaust pipe connected to a side surface of the heat insulating chamber vertically between the inert gas supplier and the process chamber; and a second exhauster provided with a second exhaust pipe connected to the process chamber.

### CROSS-REFERENCE TO RELATED PATENT APPLICATION

This application is a bypass continuation application of PCT International Application No. PCT/JP2022/031771, filed on Aug. 23, 2022, in the WIPO, the entire contents of which are hereby incorporated by reference.

### FIELD

The present disclosure relates to a substrate processing apparatus, a substrate processing method, a method of manufacturing a semiconductor device and a non-transitory computer-readable recording medium.

### RELATED ART

A substrate processing apparatus using a reaction tube may be used. According to some related arts, in such a reaction tube, a process gas may be supplied to a substrate along a horizontal direction and exhausted along the horizontal direction.

In the substrate processing apparatus mentioned above, when a purge gas is supplied to the periphery of a rotation shaft (which is provided below a process chamber of the substrate processing apparatus), the purge gas may flow into the process chamber from thereunder. Thereby, a uniformity of a substrate processing may deteriorate.

### SUMMARY

According to the present disclosure, there is provided a technique capable of improving a uniformity of a substrate processing.

According to an embodiment of the present disclosure, there is provided a technique that includes: a process chamber in which a substrate is processed; a process gas supplier capable of supplying a process gas to the process chamber; a heater capable of heating the process chamber; a heat insulating chamber constituting a heat insulating region provided below the process chamber; an inert gas supplier capable of supplying an inert gas to the heat insulating chamber from thereunder; a first exhauster provided with a first exhaust pipe connected to a side surface of the heat insulating chamber vertically between the inert gas supplier and the process chamber; and a second exhauster provided with a second exhaust pipe connected to the process chamber

### BRIEF DESCRIPTION OF THE DRAWINGS

FIG. 1 is a diagram schematically illustrating a vertical cross-section of a substrate processing apparatus according to one or more embodiments of the present disclosure.

FIG. 2A is a diagram schematically illustrating a first gas supplier according to the embodiments of the present disclosure, FIG. 2B is a diagram schematically illustrating a second gas supplier according to the embodiments of the present disclosure and FIG. 2C is a diagram schematically illustrating an inert gas supplier according to the embodiments of the present disclosure.

FIG. 3 is a diagram schematically illustrating a heat insulating chamber and components around a heat insulator according to the embodiments of the present disclosure.

FIG. 4 is a block diagram schematically illustrating a configuration of a controller and related components of the substrate processing apparatus according to the embodiments of the present disclosure.

FIG. 5 is a flow chart schematically illustrating a substrate processing flow according to the embodiments of the present disclosure.

FIG. 6 is a flow chart schematically illustrating a film processing step shown in FIG. 5.

### DETAILED DESCRIPTION

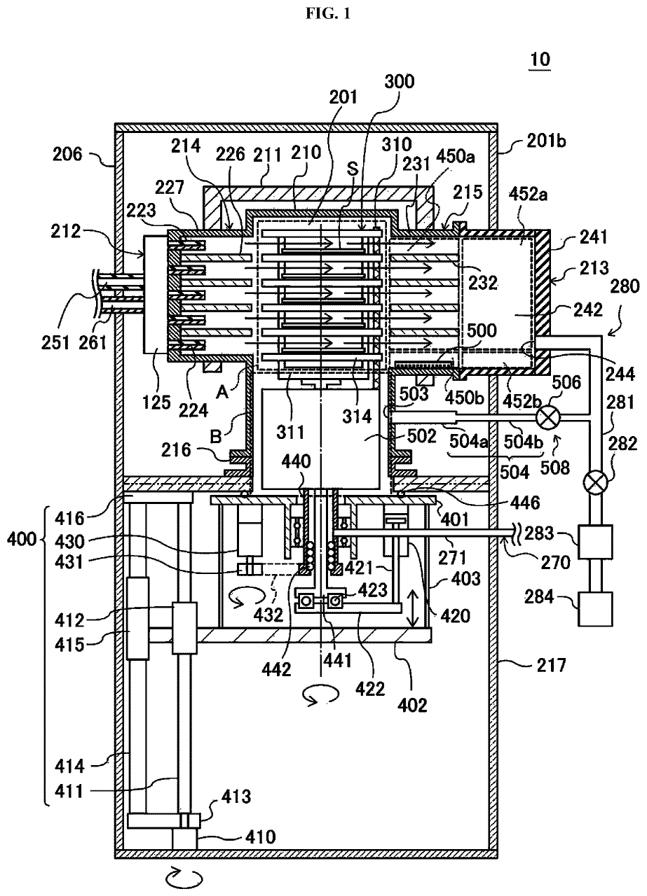

Hereinafter, one or more embodiments (also simply referred to as “embodiments”) according to the technique of the present disclosure will be described with reference to FIGS. 1 to 6. The drawings used in the following descriptions are all schematic. For example, a relationship between dimensions of each component and a ratio of each component shown in the drawing may not always match the actual ones. Further, even between the drawings, the relationship between the dimensions of each component and the ratio of each component may not always match.

### (1) Configuration of Substrate Processing Apparatus

A configuration of a substrate processing apparatus 10 according to the present embodiments will be described with reference to FIG. 1.

The substrate processing apparatus 10 includes a reaction tube storage chamber 206. In the reaction tube storage chamber 206, a reaction tube 210 of a cylindrical shape extending in a vertical direction, a heater 211 serving as a heating structure (furnace body) installed on an outer periphery of the reaction tube 210, a gas supply structure 212 serving as a part of a process gas supplier (which is a process gas supply system), and a gas exhaust structure 213 serving as a part of a process gas exhauster (which is a process gas exhaust system) are provided. The process gas supplier may further include an upstream side gas guide 214 or nozzles 223 and 224, which will be described later. Further, the process gas exhauster may further include a downstream side gas guide 215, which will be described later.

The gas supply structure 212 is provided upstream in a gas flow direction at a side of the reaction tube 210. A gas such as a process gas is supplied into a process chamber 201 in the reaction tube 210 through the gas supply structure 212. Then, the gas is supplied to the substrate S in a horizontal direction. The gas exhaust structure 213 is provided downstream in the gas flow direction at another side of the reaction tube 210, and the gas in the reaction tube 210 is discharged (exhausted) through the gas exhaust structure 213. The gas exhaust structure 213 is disposed opposite to the gas supply structure 212 with the reaction tube 210 interposed therebetween.

The process chamber 201 includes the reaction tube 210 into which the substrate S is transferred (loaded), the gas supply structure 212 and the gas exhaust structure 213. A plurality of substrates including the substrate S are processed in the process chamber 201. Hereinafter, the plurality of substrates including the substrate S may also be referred to as “substrates S”. In addition, the gas supply structure 212, an inner portion of the reaction tube 210 and the gas exhaust structure 213 communicate with one another in the horizontal direction.

On an upstream side of the reaction tube 210 between the reaction tube 210 and the gas supply structure 212, the upstream side gas guide 214 configured to adjust a flow of the gas supplied through the gas supply structure 212 is provided. Further, on a downstream side of the reaction tube 210 between the reaction tube 210 and the gas exhaust structure 213, the downstream side gas guide 215 configured to adjust the flow of the gas discharged from the reaction tube 210 is provided. A lower end of the reaction tube 210 is supported by a manifold 216.

The reaction tube 210, the upstream side gas guide 214 and the downstream side gas guide 215 are implemented as a continuous structure. For example, each of the reaction tube 210, the upstream side gas guide 214 and the downstream side gas guide 215 is made of a material such as quartz and silicon carbide (SiC). Further, each of the reaction tube 210, the upstream side gas guide 214 and the downstream side gas guide 215 is constituted by a heat transmittable structure capable of transmitting a heat radiated from the heater 211. The heat of the heater 211 can heat the substrate S and the gas. In addition, the heater 211 is disposed on a side of the process chamber 201 such that the heater 211 is configured to be capable of heating the process chamber 201.

The gas supply structure 212 is connected to each of a gas supply pipe 251 and a gas supply pipe 261. In addition, the gas supply structure 212 includes a distribution structure 125 configured to distribute gases supplied through each gas supply pipe mentioned above. A plurality of nozzles including the nozzle 223 and a plurality of nozzles including the nozzle 224 are provided at a downstream side of the distribution structure 125. Hereafter, the plurality of nozzles including the nozzle 223 may also be simply referred to as “nozzles 223”, and the plurality of nozzles including the nozzle 224 may also be simply referred to as “nozzles 224”. The nozzle 223 and the nozzle 224 are connected to a downstream side of the gas supply pipe 251 and a downstream side of the gas supply pipe 261, respectively, via the distribution structure 125. The nozzles 223 and the nozzles 224 are arranged side by side substantially in the horizontal direction. In addition, the nozzles 223 and the nozzles 224 are arranged in the vertical direction at positions corresponding to the substrates S. The process gas is supplied from beside the substrate S while the substrate S is in the process chamber 201.

The distribution structure 125 is configured such that each gas can be supplied to the nozzles 223 through the gas supply pipe 251 and to the nozzles 224 through the gas supply pipe 261. For example, a gas flow path can be provided for each combination of the gas supply pipe and the nozzle corresponding to the gas supply pipe. Thereby, since the gases respectively supplied through the gas supply pipes mentioned above are not mixed, it is possible to suppress a generation of reaction by-products (also referred to as “particles”) that may be generated when the gases are mixed in the distribution structure 125.

The upstream side gas guide 214 includes a housing 227 and a partition plate 226. The partition plate 226 extends in the horizontal direction. The “horizontal direction” of the partition plate 226 may refer to a direction toward a side wall of the housing 227. A plurality of partition plates including the partition plate 226 are arranged in the vertical direction. Hereafter, the plurality of partition plates including the partition plate 226 may also be simply referred to as “partition plates 226”. The partition plate 226 is fixed to the side wall of the housing 227 such that it is possible to prevent the gas from flowing beyond the partition plate 226 into an adjacent region below or above the partition plate 226. By preventing the gas from flowing beyond the partition plate 226, it is possible to reliably form a gas flow described later.

The partition plate 226 is a continuous structure extending in the horizontal direction and provided without a hole. The partition plates 226 are provided at positions corresponding to the substrates S, respectively. The nozzle 223 and the nozzle 224 are arranged between adjacent partition plates 226 or between the partition plate 226 and the housing 227.

The gas ejected through the nozzle 223 or the nozzle 224 is supplied to a surface of the substrate S. That is, when viewed from the substrate S, the gas is supplied along a lateral direction of the substrate S. Since the partition plate 226 is a continuous structure extending in the horizontal direction and provided without a hole, a mainstream of the gas is restrained from flowing in the vertical direction and flows in the horizontal direction. Therefore, a pressure loss of the gas reaching each substrate S can be uniformized along the vertical direction.

The downstream side gas guide 215 is configured such that a ceiling thereof is provided above an uppermost substrate among the substrates S supported by a substrate support 300 described later, and a bottom thereof is provided below a lowermost substrate among the substrates S supported by the substrate support 300. The substrate support 300 is used as a substrate retainer capable of holding (or supporting) the substrates S.

The downstream side gas guide 215 includes a housing 231 and a partition plate 232. The partition plate 232 extends in the horizontal direction. The “horizontal direction” of the partition plate 232 may refer to a direction toward a side wall of the housing 231. Further, a plurality of partition plates including the partition plate 232 are arranged in the vertical direction. Hereafter, the plurality of partition plates including the partition plate 232 may also be simply referred to as “partition plates 232”. The partition plate 232 is fixed to the side wall of the housing 231 such that it is possible to prevent the gas from flowing beyond the partition plate 232 into an adjacent region below or above the partition plate 232. By preventing the gas from flowing beyond the partition plate 232, it is possible to reliably form the gas flow described later.

The upstream side gas guide 214 communicates with a space within the downstream side gas guide 215 via the process chamber 201. A ceiling of the housing 227 is provided at the same height as a ceiling of the housing 231. In addition, a bottom of the housing 227 is provided higher than a bottom of the housing 231. In other words, the bottom of the housing 231 is provided lower than the bottom of the housing 227, and the space within the downstream side gas guide 215 is wider than a space within the upstream side gas guide 214.

The space within the downstream side gas guide 215 includes: a region 450a whose volume is the same as the space within the upstream side gas guide 214; and a region 450b provided below the region 450a. The region 450b is arranged lower than a lower surface of the lowermost substrate among the substrates S stacked in the substrate support 300 while the substrate support 300 is transferred (loaded) into the process chamber 201.

The partition plate 232 is a continuous structure extending in the horizontal direction and provided without a hole. The partition plates 232 are provided at positions corresponding to the substrates S and corresponding to the partition plates 226, respectively. It is preferable that the partition plate 226 and the partition plate 232 corresponding to the partition plate 226 are provided at the same height. Further, when processing the substrate S, it is preferable that the substrate S, the partition plate 226 corresponding to the substrate S and the partition plate 232 corresponding to the partition plate 226 are provided at the same height. With such a structure, the gas flow in the horizontal direction passing over the substrate S and the partition plate 232 is formed by the gas supplied through each nozzle, as shown by each arrow in FIG. 1. By configuring the partition plate 232 as described above, it is possible to uniformize the pressure loss of the gas ejected (or discharged) through each of the substrates S. Therefore, the flow of the gas passing through each of the substrates S is formed in the horizontal direction toward the gas exhaust structure 213 while suppressing a gas flow in the vertical direction.

By providing the partition plates 226 and the partition plates 232, it is possible to uniformize the pressure loss in the vertical direction at both an upstream and a downstream of each of the substrates S. As a result, it is possible to reliably form a horizontal gas flow over the partition plate 226, the substrate S and the partition plate 232 while suppressing a vertical gas flow.

The gas exhaust structure 213 is provided downstream of the downstream side gas guide 215. The gas exhaust structure 213 is constituted mainly by a housing 241 and an exhaust hole 244. The exhaust hole 244 is provided at a downstream side of the housing 241 on a lower portion of the housing 241 in the horizontal direction. A second exhaust pipe 281 is connected to the process chamber 201 via the exhaust hole 244.

The gas exhaust structure 213 communicates with the space within the downstream side gas guide 215. The housing 231 and the housing 241 may form a structure with a continuous height. That is, a height of the ceiling of the housing 231 is configured to be the same as that of a ceiling of the housing 241, and a height of the bottom of the housing 231 is configured to be the same as that of a bottom of the housing 241. The gas exhaust structure 213 includes: a region 452a provided adjacent to the region 450a of the downstream side gas guide 215; and a region 452b provided adjacent to the region 450b of the downstream side gas guide 215 and provided below the region 452a.

The gas exhaust structure 213 is provided in a lateral direction of the reaction tube 210, and is a lateral exhaust structure configured to exhaust the gas along the lateral direction of the substrate S.

A first region is constituted by the region 450a of the downstream side gas guide 215 and the region 452a of the gas exhaust structure 213. A second region is constituted by the region 450b of the downstream side gas guide 215 and the region 452b of the gas exhaust structure 213. The process chamber 201 includes: a processing region A in which the substrate S is processed; and a heat insulating chamber 505 provided below the processing region A and constituting a heat insulating region B in which a heat insulator (which is a heat insulating structure) 502 is disposed while the substrate support 300 is transferred (loaded) into the process chamber 201. The first region is adjacent to the processing region A in the horizontal direction.

The second region (that is, the region 450b or the region 452b) is configured such that a thermocouple 500 can be installed therein. By providing the second region, it is possible to prevent (or suppress) an inert gas supplied to the heat insulator 502 or an atmosphere (including the reaction by-products) of the heat insulating chamber 505 from flowing into the processing region A. Therefore, the flow of the gas passing through each of the substrates S is formed in the horizontal direction toward the gas exhaust structure 213 while suppressing the gas flow in the vertical direction.

That is, the gas that has passed through the downstream side gas guide 215 is exhausted through the exhaust hole 244. When the gas is exhausted through the exhaust hole 244, since the gas exhaust structure 213 is not provided with a structure similar to the partition plate described above, the gas flow whose vertical component is non-zero is formed toward the exhaust hole 244.

The substrate support 300 includes a partition plate support 310 and a base structure 311, and is accommodated in the reaction tube 210. The substrates S are arranged directly below an inner wall of a top plate of the reaction tube 210. Further, the substrate support 300 is configured such that a process of moving the substrate S by a vacuum transfer robot in a transfer chamber 217 via a substrate loading/unloading port (not shown) can be performed and a process of loading the substrate S (which is replaced) into the reaction tube 210 and forming a film on the surface of the substrate S can be performed. For example, the substrate loading/unloading port is provided on a side wall of the transfer chamber 217.

A plurality of partition plates including a partition plate 314 of a disk shape are fixed to the partition plate support 310 at a predetermined pitch therebetween. Hereafter, the plurality of partition plates including the partition plate 314 may also be simply referred to as “partition plates 314”. The substrates S are placed between the partition plates 314 at a predetermined interval therebetween. The partition plate 314 may be arranged directly below the substrate S. The partition plates 314 may be provided above and/or below the substrate S. The partition plates 314 are configured to separate the spaces between adjacent substrates S from one another.

The substrates S are stacked and placed on the substrate support 300 at the predetermined vertical interval therebetween. The predetermined interval between the substrates S placed on the substrate support 300 is the same as a vertical interval (that is, the pitch described above) between the partition plates 314 fixed to the partition plate support 310. Further, a diameter of the partition plate 314 is set to be larger than a diameter of the substrate S.

The substrate support 300 is configured to support a plurality of substrates (for example, 5 substrates) as the substrates S in a multistage manner in the vertical direction. Further, the present embodiments will be described by way of an example in which 5 substrates are supported by the substrate support 300 as the substrates S. However, the present embodiments are not limited thereto. For example, the substrate support 300 may be configured to support about 5 substrates to 50 substrates as the substrates S. Further, the partition plate 314 of the partition plate support 310 may also be referred to as a “separator”.

The substrate support 300 is driven by a vertical driving structure 400 in the vertical direction between the reaction tube 210 and the transfer chamber 217 and in a rotational direction around a center of the substrate S supported by the substrate support 300.

The heat insulator 502, which will be described in detail later, is provided below the substrate support 300. The heat insulating chamber 505 of a cylindrical shape is provided in the process chamber 201 of the reaction tube 210. The heat insulating chamber 505 is configured to accommodate (or store) the heat insulator 502 when the substrate support 300 is loaded into the reaction tube 210. The heat insulating chamber 505 is of a cylindrical shape. The heat insulating chamber 505 is configured such that a constant distance between an outer wall of the heat insulator 502 and an inner wall of the heat insulating chamber 505 can be maintained when the substrate support 300 is loaded into the reaction tube 210. An exhaust hole 503 is provided on a side surface of the heat insulating chamber 505. A first exhaust pipe 504 through which an atmosphere (inner atmosphere) of the heat insulating region B is exhausted is connected to the heat insulating chamber 505 so as to communicate with the exhaust hole 503.

The transfer chamber 217 is installed below the reaction tube 210 via the manifold 216. In the transfer chamber 217, the substrate S may be transferred to (or placed on) the substrate support (hereinafter, may also be simply referred to as a “boat”) 300 by the vacuum transfer robot via the substrate loading/unloading port, or the substrate S may be transferred (or taken) out of the substrate support 300 by the vacuum transfer robot.

Inside the transfer chamber 217, the vertical driving structure (vertical driver) 400 constituting a first driving structure (first driver) configured to drive the substrate support 300 in the vertical direction and the rotational direction can be accommodated (or stored). FIG. 1 shows a state in which the substrate support 300 is elevated by the vertical driving structure 400 and stored in the reaction tube 210. Further, while the substrate support 300 is accommodated in the reaction tube 210, the heat insulator 502 is disposed at a lower portion of the reaction tube 210 to form the heat insulating chamber 505. That is, the heat insulator 502 is configured to form the heat insulating region B provided below the process chamber 201. Thereby, it is possible to reduce a thermal conduction to the transfer chamber 217 from the process chamber 201.

The vertical driving structure 400 constituting the first driving structure may include: as drive sources, a vertical driving motor 410; a rotational driving motor 430; and a boat vertical driving structure (boat vertical driver) 420 provided with a linear actuator serving as a substrate support elevator capable of driving the substrate support 300 in the vertical direction.

By rotationally driving a ball screw 411, the vertical driving motor 410 serving as a partition plate support elevator moves a nut 412 screwed with respect to the ball screw 411 in the vertical direction (up-and-down direction) along the ball screw 411. As a result, the partition plate support 310 and the substrate support 300 are driven in the vertical direction between the reaction tube 210 and the transfer chamber 217 together with a base plate 402 fixing the nut 412. The base plate 402 is also fixed to a ball guide 415 that is engaged with a guide shaft 414, and is configured to be capable of being smoothly moved in the vertical direction along the guide shaft 414. An upper end portion and a lower end portion of each of the guide shaft 414 and the ball screw 411 are fixed to fixing plates 416 and 413, respectively.

The rotational driving motor 430 and the boat vertical driving structure 420 provided with the linear actuator constitute a second driving structure (second driver), and are fixed to a base flange 401 serving as a lid supported by a side plate 403 on the base plate 402.

The rotational driving motor 430 is configured to drive a rotation transmission belt 432 that engages with a tooth structure 431 attached to a front end (tip) thereof, and is configured to rotationally drive a support 440 that engages with the rotation transmission belt 432. The support 440 is configured to support the partition plate support 310 by the base structure 311, and is configured to rotate the partition plate support 310 and the substrate support 300 by being driven by the rotational driving motor 430 via the rotation transmission belt 432.

The boat vertical driving structure 420 provided with the linear actuator is configured to drive a shaft 421 in the vertical direction. A plate 422 is attached to a front end (tip) of the shaft 421. The plate 422 is connected to a support 441 fixed to the substrate support 300 via a bearing 423. By connecting the support 441 to the plate 422 via the bearing 423, when the partition plate support 310 is rotationally driven by the rotational driving motor 430, it is possible to rotate the substrate support 300 together with the partition plate support 310.

On the other hand, the support 441 is supported by the support 440 via a linear guide bearing 442. With such a configuration, when the shaft 421 is driven in the vertical direction by the boat vertical driving structure 420 provided with the linear actuator, it is possible to drive the support 441 fixed to the substrate support 300 in the vertical direction relative to the support 440 fixed to the partition plate support 310.

An annular space is provided between the support 441 and the support 440. A gas supply pipe 271 is connected to the annular space below the heat insulator 502. The inert gas is supplied through the gas supply pipe 271 such that the inert gas is supplied to the heat insulator 502 from thereunder.

An O-ring 446 for a vacuum seal is installed on an upper surface of the base flange 401 serving as the lid, and as shown in FIG. 1, by driving the vertical driving motor 410 such that the upper surface of the base flange 401 is elevated to a position where it is pressed against the transfer chamber 217, it is possible to maintain an inside of the reaction tube 210 airtight.

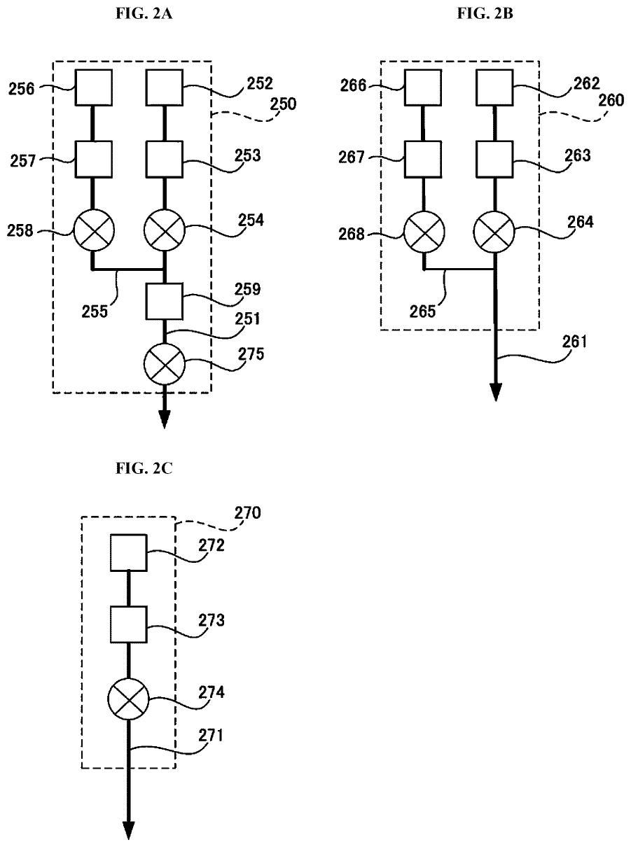

Subsequently, a gas supplier (which is a gas supply system) will be described in detail with reference to FIGS. 2A through 2C.

As shown in FIG. 2A, a first gas supply source 252, a mass flow controller (MFC) 253 serving as a flow rate controller (a flow rate control structure), a valve 254 serving as an opening/closing valve, a tank 259 serving as a storage configured to store a gas and a valve 275 serving as an opening/closing valve are sequentially installed at the gas supply pipe 251 in this order from an upstream side to a downstream side of the gas supply pipe 251.

The first gas supply source 252 is a source of a first gas containing a first element (also referred to as a “first element-containing gas”). The first gas serves as a source gas, that is, one of process gases.

A first gas supplier (which is a first gas supply system) 250 is constituted mainly by the gas supply pipe 251, the MFC 253, the valve 254, the tank 259 and the valve 275. The first gas supplier 250 may also be referred to as a “silicon-containing gas supplier” which is a silicon-containing gas supply system. The first gas supplier 250 may further include the first gas supply source 252.

A gas supply pipe 255 is connected to the gas supply pipe 251 at a downstream side of the valve 254 and an upstream side of the tank 259. An inert gas supply source 256, an MFC 257 and a valve 258 are sequentially installed at the gas supply pipe 255 in this order from an upstream side to a downstream side of the gas supply pipe 255. An inert gas (for example, nitrogen (N₂) gas) is supplied from the inert gas supply source 256.

A first inert gas supplier (which is a first inert gas supply system) is constituted mainly by the gas supply pipe 255, the MFC 257 and the valve 258. The inert gas supplied from the inert gas supply source 256 acts as a purge gas for purging the gas remaining in the reaction tube 210 when performing a substrate processing described later. The first inert gas supplier may further include the inert gas supply source 256. The first gas supplier 250 may further include the first inert gas supplier.

As shown in FIG. 2B, a second gas supply source 262, an MFC 263 and a valve 264 are sequentially installed at the gas supply pipe 261 in this order from an upstream side to a downstream side of the gas supply pipe 261.

The second gas supply source 262 is a source of a second gas containing a second element (also referred to as a “second element-containing gas”). The second gas serves as one of the process gases. Further, the second gas may serve as a reactive gas or a modification gas. A second gas supplier (which is a second gas supply system) 260 is constituted mainly by the gas supply pipe 261, the MFC 263 and the valve 264. The second gas supplier 260 may further include the second gas supply source 262.

A gas supply pipe 265 is connected to the gas supply pipe 261 at a downstream side of the valve 264. An inert gas supply source 266, an MFC 267 and a valve 268 are sequentially installed at the gas supply pipe 265 in this order from an upstream side to a downstream side of the gas supply pipe 265. The inert gas (for example, the N₂ gas) is supplied from the inert gas supply source 266.

A second inert gas supplier (which is a second inert gas supply system) is constituted mainly by the gas supply pipe 265, the MFC 267 and the valve 268. The inert gas supplied from the inert gas supply source 266 acts as the purge gas for purging the gas remaining in the reaction tube 210 when performing the substrate processing described later. The second inert gas supplier may further include the inert gas supply source 266. The second gas supplier 260 may further include the second inert gas supplier.

As shown in FIG. 2C, an inert gas supply source 272, an MFC 273 and a valve 274 are sequentially installed at the gas supply pipe 271 in this order from an upstream side to a downstream side of the gas supply pipe 271. The inert gas (for example, the N₂ gas) is supplied from the inert gas supply source 272.

An inert gas supplier (which is an inert gas supply system) 270 is constituted mainly by the gas supply pipe 271, the MFC 273 and the valve 274. The inert gas supplied from the inert gas supply source 272 acts as the purge gas capable of purging the heat insulating chamber 505 constituting the heat insulating region B disposed below the process chamber 201 when performing the substrate processing described later while the substrate support 300 is transferred into the process chamber 201. The inert gas supplier 270 may further include the inert gas supply source 272.

Subsequently, an exhauster (which is an exhaust system) will be described.

A vacuum pump 284 serving as a vacuum exhaust apparatus is connected to the second exhaust pipe 281 via a valve 282 and an APC (Automatic Pressure Controller) valve 283 serving as a pressure regulator (which is a pressure adjusting structure). Thereby, the reaction tube 210 can be vacuum-exhausted such that an inner pressure of the reaction tube 210 reaches and is maintained at a predetermined pressure (vacuum degree).

A second exhauster (which is a second exhaust system) 280 is constituted by the second exhaust pipe 281, the valve 282 and the APC valve 283. Further, the second exhauster 280 may further include the vacuum pump 284. That is, the second exhauster 280 includes the second exhaust pipe 281 communicating with the process chamber 201 of the reaction tube 210, and is configured to exhaust an atmosphere (inner atmosphere) of the process chamber 201 through the second exhaust pipe 281. The second exhauster 280 is configured to be capable of exhausting the process gas along a direction away from the side of the reaction tube 210 from which the process gas is supplied.

The first exhaust pipe 504 is constituted by an upstream pipe 504a (also simply referred to as a “pipe 504a”) and a downstream pipe 504b (also simply referred to as a “pipe 504b”). A valve 506 is provided at the pipe 504b. A downstream end of the pipe 504b is connected to the second exhaust pipe 281 at a confluence portion provided at an upstream side of the valve 282 of the second exhaust pipe 281. In other words, the first exhaust pipe 504 is connected to the second exhaust pipe 281 such that the valve 282 is located at a downstream side of the confluence portion of the second exhaust pipe 281. Thereby, as compared with a case where the first exhaust pipe 504 is connected to the second exhaust pipe 281 at a downstream side of the valve 282, it is possible to reduce the number of control parameters.

In addition, an inner diameter of the upstream pipe 504a is set to be larger than an inner diameter of the downstream pipe 504b. By setting the inner diameter of the downstream pipe 504b smaller than the inner diameter of the upstream pipe 504a, it is possible to install a valve such as a butterfly valve capable of adjusting a flow rate of the gas in the downstream pipe 504b at a low cost.

The heat insulating chamber 505 is provided below the process chamber 201 when the substrate support 300 is loaded into the reaction tube 210. In addition, the heat insulating chamber 505 is configured such that the first exhaust pipe 504 is connected to a side of the heat insulating chamber 505 vertically between the inert gas supplier 270 and the process chamber 201. A connection location of the first exhaust pipe 504 is also disposed at a side of the heat insulator 502 when the substrate support 300 is loaded into the reaction tube 210. Thereby, the inert gas supplied to the heat insulating chamber 505 from thereunder can flow through the heat insulating region B (that is, a region inside the heat insulating chamber 505) and can be exhausted from the side of the heat insulating chamber 505.

That is, the process gas supplied to the processing region A is exhausted separately via the second exhaust pipe 281, and the inert gas supplied to the heat insulating region B is exhausted separately via the first exhaust pipe 504. Thus, while suppressing an adhesion of the reaction by-products by purging the heat insulating region B with the inert gas, it is possible to suppress an effect of the inert gas on the processing region A.

Further, the first exhaust pipe 504 is disposed below the heater 211. Therefore, the first exhaust pipe 504 does not interfere with the heating. Thereby, it is possible to improve the space efficiency. In addition, the heater 211 can be disposed adjacent to the substrates S stacked from the bottom to the top. As a result, it is possible to uniformly heat the substrates S.

A first exhauster (which is a first exhaust system) 508 is constituted by the pipe 504a, the pipe 504b and the valve 506. The first exhauster 508 includes the first exhaust pipe 504 communicating with the heat insulating region B of the reaction tube 210, and is configured to exhaust the inert gas supplied to the heat insulating region B and the atmosphere of the heat insulating region B.

In addition, an inner diameter of the first exhaust pipe 504 is set to be smaller than an inner diameter of the second exhaust pipe 281. In addition, a conductance of the first exhaust pipe 504 is set to be smaller than a conductance of the second exhaust pipe 281. For example, a conductance ratio of the first exhaust pipe 504 to the second exhaust pipe 281 is set to be about 1:500.

As a result, even when a flash supply is performed in which a large amount of the process gas is temporarily supplied to the substrate S during the substrate processing described later, the large amount of the process gas supplied to the substrate S can be exhausted via the second exhaust pipe 281. In addition, by reducing the conductance of the first exhaust pipe 504, it is possible to prevent the process gas supplied to the process chamber 201 from flowing into the heat insulating region B.

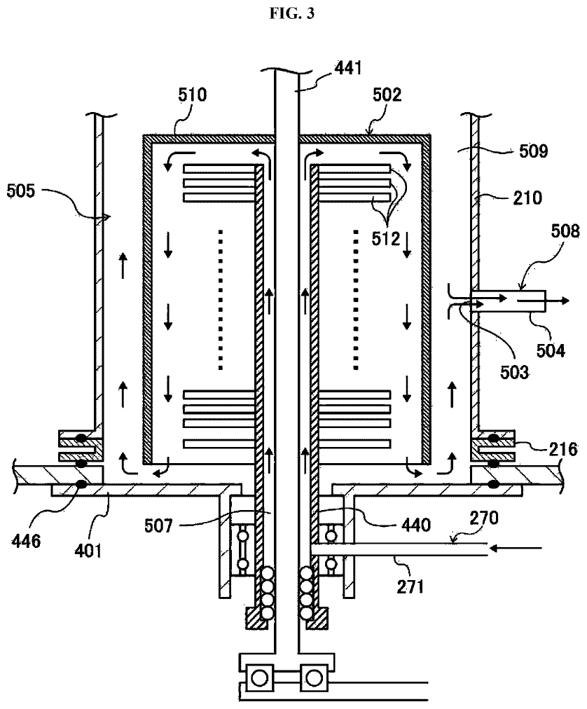

Subsequently, the heat insulating chamber 505 and components around the heat insulator 502 will be described in detail with reference to FIG. 3.

The heat insulator 502 is constituted by a heat insulating housing 510 and a plurality of heat insulating plates 512 serving as a heat insulating material. Hereinafter, each of the heat insulating plates 512 may also be referred to as a “heat insulating plate 512”. The heat insulating housing 510 is of a cylindrical shape with an upper surface and side surfaces. Further, the support 441 supporting the substrate support 300 penetrates a center of the upper surface of the heat insulating housing 510 and is fixed to the heat insulating housing 510. In the heat insulating housing 510, the support 440 and the heat insulating plates 512 (which are stacked approximately horizontally in the vertical direction relative to the support 440) are accommodated. The heat insulating housing 510 is configured to cover an upper portion of the support 440. The support 441 contains a metal component.

For example, the heat insulating plate 512 is made of a heat resistant material such as quartz and SiC. Thereby, it is difficult for the heat to be transmitted from the process chamber 201 to the transfer chamber 217. The heat insulating material is not limited to the heat insulating plates 512. For example, a heat insulating cylinder made of a heat resistant material such as quartz and SiC may be provided as the heat insulating material.

As described above, the annular space is provided between the support 441 and the support 440. The annular space is used as an inert gas flow passage 507 through which the inert gas flows. The gas supply pipe 271 is connected to the inert gas flow passage 507. The inert gas supplied through the gas supply pipe 271 is supplied into the heat insulating housing 510 through the inert gas flow passage 507, and flows downward from a lower portion of the heat insulating housing 510 to an outside of the heat insulating housing 510. Then, the inert gas is exhausted through the first exhauster 508 via the upper surface of the base flange 401, an inert gas flow passage 509 (which is a space between an outer surface of the heat insulating housing 510 and the reaction tube 210) and the exhaust hole 503. That is, the inert gas supplied through the gas supply pipe 271 purges the heat insulating chamber 505 (which is the heat insulating region B), and is exhausted through the first exhauster 508. Therefore, when the support 441 is made of the metal component, the metal component precipitated from the support 441 due to an influence of the heat or the like is exhausted through the first exhauster 508. That is, it is possible to prevent (or suppress) the metal component from entering the process chamber 201.

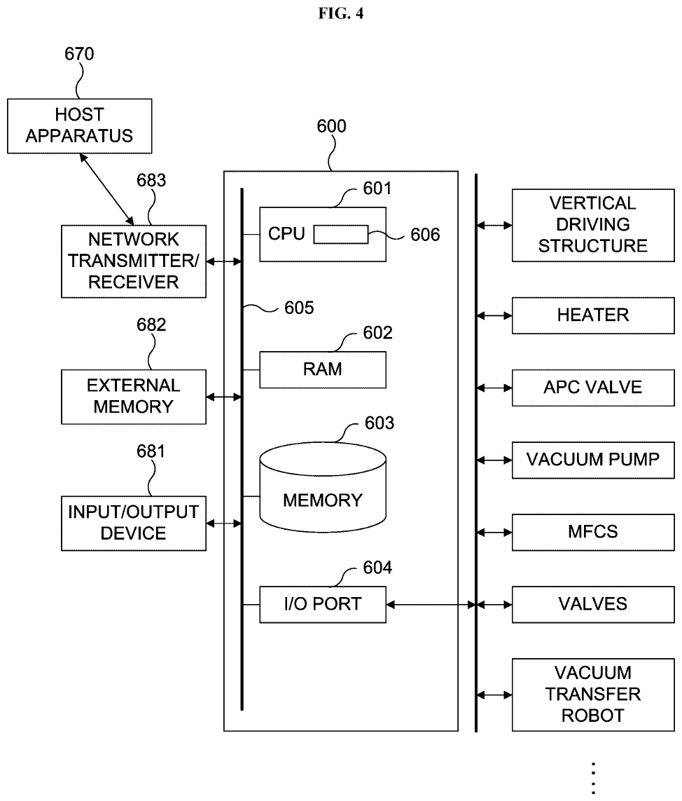

Subsequently, a controller 600 serving as a control structure (control apparatus) will be described with reference to FIG. 4. The substrate processing apparatus 10 includes the controller 600 configured to control operations of components constituting the substrate processing apparatus 10.

FIG. 4 is a diagram schematically illustrating a configuration of the controller 600. The controller 600 may be constituted by a computer including a CPU (Central Processing Unit) 601, a RAM (Random Access Memory) 602, a memory 603 serving as a memory structure and an I/O port (input/output port) 604. The RAM 602, the memory 603 and the I/O port 604 can exchange data with the CPU 601 via an internal bus 605. The transmission/reception of the data in the substrate processing apparatus 10 may be performed by an instruction from a transmission/reception instruction controller 606 which is one of functions of the CPU 601.

A network transmitter/receiver 683 connected to a host apparatus 670 via a network is provided at the controller 600. For example, the network transmitter/receiver 683 is capable of receiving data such as information regarding a processing history and a processing schedule for the substrate S stored in a pod from the host apparatus 670.

For example, the memory 603 may be embodied by a component such as a flash memory and a HDD (Hard Disk Drive). The memory 603 stores process conditions for each type of substrate processing. That is, a control program for controlling the operations of the substrate processing apparatus 10 or a process recipe in which information such as procedures and conditions of the substrate processing is stored may be readably stored in the memory 603.

The process recipe is obtained by combining steps of the substrate processing described later, and acts as a program that is executed by the controller 600 to obtain a predetermined result by performing the steps of the substrate processing described later. Hereinafter, the process recipe and the control program may be collectively or individually referred to simply as a “program”. Thus, in the present specification, the term “program” may refer to the process recipe alone, may refer to the control program alone, or may refer to both of the process recipe and the control program. The RAM 602 serves as a memory area (work area) in which the program or the data read by the CPU 601 is temporarily stored.

The I/O port 604 is electrically connected to the components of the substrate processing apparatus 10 described above.

The CPU 601 is configured to read and execute the control program from the memory 603, and is configured to read the process recipe from the memory 603 in accordance with an instruction such as an operation command inputted from an input/output device 681. The CPU 601 is configured to be capable of controlling the substrate processing apparatus 10 in accordance with contents of the read process recipe. The CPU 601 is further configured to be capable of setting an amount (supply amount) of the inert gas supplied to the heat insulating chamber 505 in accordance with the type of substrate processing. The CPU 601 is further configured to be capable of individually controlling the first exhauster 508 communicating with the heat insulating chamber 505 and the second exhauster 280 communicating with the processing region A in accordance with the type and the conditions of the substrate processing.

The CPU 601 includes the transmission/reception instruction controller 606. For example, the controller 600 according to the present embodiments may be embodied by preparing an external memory 682 (for example, a magnetic disk such as a hard disk, an optical disk such as a DVD, a magneto-optical disk such as an MO, a semiconductor memory such as a USB memory) storing the program described above and by installing the program onto the computer by using the external memory 682. Further, a method of providing the program to the computer is not limited to a method using the external memory 682. For example, the program may be directly provided to the computer by a communication interface such as the Internet and a dedicated line instead of the external memory 682. Further, the memory 603 and the external memory 682 may be embodied by a non-transitory computer-readable recording medium. Hereinafter, the memory 603 and the external memory 682 may be collectively or individually referred to as a “recording medium”. Thus, in the present specification, the term “recording medium” may refer to the memory 603 alone, may refer to the external memory 682 alone, or may refer to both of the memory 603 and the external memory 682.

### (2) Substrate Processing

Hereinafter, as a part of a manufacturing process of a semiconductor device, the substrate processing will be described by way of an example in which a film forming process of forming a film on the substrate S is performed by using the substrate processing apparatus 10 described above. Further, in the following description, the controller 600 controls the operations of the components constituting the substrate processing apparatus 10.

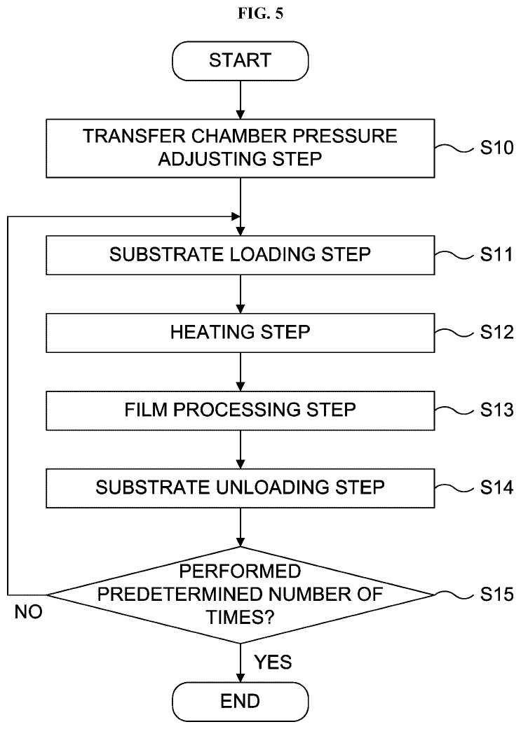

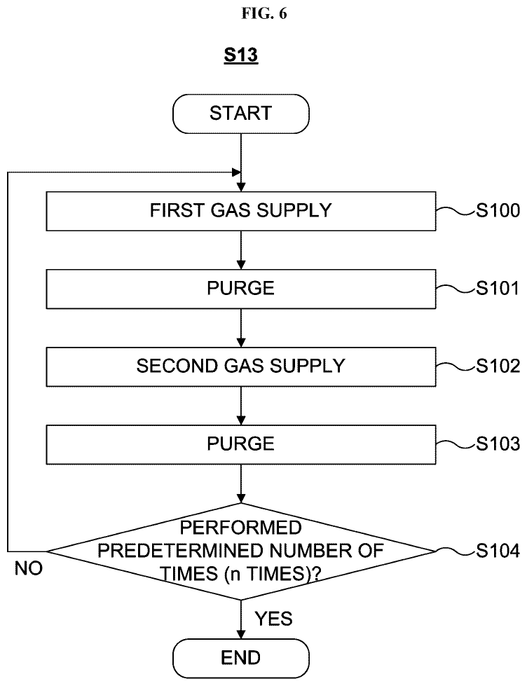

Hereinafter, the film forming process will be described with reference to FIGS. 5 and 6 by way of an example in which the film is formed on the substrate S by using the first gas and the second gas as the process gases and by alternately supplying the first gas and the second gas.

In the present specification, the term “substrate” may refer to “a substrate itself”, or may refer to “a substrate and a stacked structure (aggregated structure) of a predetermined layer (or layers) or a film (or films) formed on a surface of the substrate”. In the present specification, the term “a surface of a substrate” may refer to “a surface of a substrate itself”, or may refer to “a surface of a predetermined layer (or a predetermined film) formed on a substrate”. Thus, in the present specification, “forming a predetermined layer (or a film) on a substrate” may refer to “forming a predetermined layer (or a film) directly on a surface of a substrate itself”, or may refer to “forming a predetermined layer (or a film) on a surface of another layer (or another film) formed on a substrate”. In the present specification, the terms “substrate” and “wafer” may be used as substantially the same meaning.

### <S10>

A transfer chamber pressure adjusting step S10 will be described. In the present step, an inner pressure of the transfer chamber 217 is set to the same level as that of a vacuum transfer chamber (not shown) provided adjacent to the transfer chamber 217.

### <S11>

Subsequently, a substrate loading step S11 will be described. When the inner atmosphere of the transfer chamber 217 reaches and is maintained at the vacuum level, a transfer of the substrate S is started. When the substrate S reaches the vacuum transfer chamber, a gate valve is opened. Then, the substrate S is loaded (transferred) into the transfer chamber 217 by the vacuum transfer robot.

In the present step, the substrate support 300 stands by in the transfer chamber 217, and the substrate S is transferred to the substrate support 300. When a predetermined number of the substrates S are transferred to the substrate support 300, the vacuum transfer robot is retracted, and the substrate support 300 is elevated by the vertical driving structure 400 to move the substrates S into the process chamber 201 in the reaction tube 210. The substrates S are moved into the process chamber 201 while stacked in the vertical direction.

When moving the substrate S to the reaction tube 210, the surface of the substrate S is positioned so as to be aligned at the same height as the partition plate 226 and the partition plate 232.

### <S12>

Subsequently, a heating step S12 will be described. When the substrate S is loaded into the process chamber 201 in the reaction tube 210, the inner pressure of the reaction tube 210 is controlled (adjusted) to a predetermined pressure and a surface temperature of the substrate S is controlled to a predetermined temperature. In such a state, the heater 211 is adjacent to the substrates S.

### <S13>

Subsequently, a film processing step S13 will be described. The film processing step S13 is performed by performing the following steps S100 to S104 to the substrate S in accordance with the process recipe while the substrates S are stacked on the substrate support 300 and accommodated in the process chamber 201.

### <First Gas Supply, Step S100>

First, the first gas is supplied into the reaction tube 210 in a flash-like manner (that is, a large amount of the first gas is temporarily supplied into the reaction tube 210). Specifically, the valve 275 is opened so as to supply the first gas into the gas supply pipe 251 from the tank 259 in which the first gas is stored in advance. After a predetermined time has elapsed, the valve 275 is closed to stop a supply of the first gas into the gas supply pipe 251. The first gas is supplied in a large amount at once into the reaction tube 210 from the gas supply structure 212 via the distribution structure 125, the nozzles 223 and the upstream side gas guide 214. Then, the first gas is exhausted through the space on the substrate S, the downstream side gas guide 215, the gas exhaust structure 213 and the second exhaust pipe 281. In the present step, while the first gas is being supplied into the process chamber 201, the valve 254 may be opened or closed. Further, when the first gas is being supplied, the valve 258 may be opened so as to supply the inert gas such as the N₂ gas into the gas supply pipe 251 via the gas supply pipe 255. Further, when the first gas is being supplied, in order to prevent the first gas from entering the gas supply pipe 261, the valve 268 may be opened so as to supply the inert gas into the gas supply pipe 261.

In the present step, for example, the APC valve 283 is appropriately adjusted such that the inner pressure of the reaction tube 210 is set to be a pressure within a range from 1 Pa to 3,990 Pa. In the following, for example, a temperature of the heater 211 is adjusted such that a temperature of the substrate S reaches and is maintained at a temperature within a range from 100° C. to 1,500° C., preferably from 400° C. to 800° C.

Further, in the present specification, a notation of a numerical range such as “from 1 Pa to 3,990 Pa” means that a lower limit and an upper limit are included in the numerical range. Therefore, for example, a numerical range “from 1 Pa to 3,990 Pa” means a range equal to or higher than 1 Pa and equal to or lower than 3,990 Pa. The same also applies to other numerical ranges described in the present specification.

In the present step, the first gas is supplied in a large amount at once from beside the substrate S to the substrate S in the horizontal direction through the gas supply structure 212 (which is in communication with the inner portion of the reaction tube 210), and is exhausted through the second exhaust pipe 281. For example, the inner diameter of the second exhaust pipe 281 is set to be 200 Å. For example, a flow rate of the gas exhausted through the second exhaust pipe 281 at once is set to be 0.5 l/h (liter/hour).

In addition, in the present step, the valve 274 is opened, and the valve 506 is controlled not to be fully closed, preferably to be fully opened. The inert gas whose flow rate is adjusted by the MFC 273 is supplied into the heat insulating housing 510 from the gas supply structure 212 via the gas supply pipe 271 and the inert gas flow passage 507. Further, the inert gas flows downward from the lower portion of the heat insulating housing 510 to the outside of the heat insulating housing 510, and is supplied to the upper surface of the base flange 401 and the inert gas flow passage 509. Then, the inert gas is exhausted through the first exhaust pipe 504 via the exhaust hole 503. For example, the inner diameter of the first exhaust pipe 504 is set to be 50 Å. For example, a supply amount of the inert gas in the present step is set to be 0.1 liter to 2.0 liters. For example, a flow rate of the gas exhausted through the first exhaust pipe 504 is set to be 50 1/h (liter/hour). By supplying the first gas in the flash-like manner described above, a pressure in the upper portion of the process chamber 201 is momentarily increased. Therefore, the supply amount of the inert gas supplied through the inert gas supplier 270 to the heat insulating chamber 505 is set to be greater than that of the inert gas during a purge described later.

That is, in a state where the substrate S loaded into the process chamber 201 is heated, while the first gas is supplied to the processing region A for the substrate S, which is the process chamber 201, the valve 282 is opened to exhaust the gas through the second exhaust pipe 281. Further, in the present step, while the inert gas is supplied by the inert gas supplier 270 to the heat insulating region B below the processing region A, the valve 506 is opened to exhaust the gas through the first exhaust pipe 504. That is, opening and closing operations of the valves 506 and 282 are controlled simultaneously. With such a configuration, by exhausting the atmosphere of the heat insulating chamber 505 through the first exhaust pipe 504, it is possible to suppress the adhesion of the reaction by-products to components arranged in the heat insulating chamber 505 such as the support 441 and the periphery of the valve 506.

For example, when one of the valves 506 and 282 is closed first, an atmosphere (inner atmosphere) of the first exhaust pipe 504 or an atmosphere (inner atmosphere) of the second exhaust pipe 281 may flow back into the reaction tube 210 or the heat insulating chamber 505. Further, a temperature (inner temperature) of the first exhaust pipe 504 or a temperature (inner temperature) of the second exhaust pipe 281 may be lower than a temperature (inner temperature) of the reaction tube 210. Thereby, the particles are likely to be generated. When the atmosphere of the first exhaust pipe 504 (or the atmosphere of the second exhaust pipe 281) flows back, the particles may enter the process chamber 201. Therefore, the valves 506 and 282 are controlled to open and close simultaneously. In the present specification, the term “the valves 506 and 282 are controlled to open and close simultaneously” may include a case where the valves 506 and 282 are controlled to open and close substantially simultaneously. That is, the term “the valves 506 and 282 are controlled to open and close simultaneously” may include a case where the valves 506 and 282 are controlled to open and close with a time difference that does not allow the first gas to flow back into the process chamber 201.

The first gas supplied into the process chamber 201 forms the gas flow along the upstream side gas guide 214, a space above the substrate S and the downstream side gas guide 215. In such a state, since the first gas is supplied to the substrates S without the pressure loss on each of the substrates S, it is possible to uniformly perform the substrate processing between the substrates S. By supplying the first gas from the gas supply structure 212 to the gas exhaust structure 213 in a manner described above, a side flow of the gas can be formed in the process chamber 201. Thereby, it is possible to suppress an effect of the inert gas supplied to the heat insulating chamber 505. In addition, since the inert gas supplied to the heat insulating chamber 505 flows from beside the heat insulating chamber 505 below the process chamber 201 to the first exhaust pipe 504, it is possible to suppress an effect of the inert gas supplied to the heat insulating chamber 505 on the processing region A.

That is, it is possible to suppress an effect of the side flow on the lowermost substrate (among the substrates S) disposed at a lowest position of the substrate support 300, and it is also possible to form (or provide) similar gas flows at upper and lower portions of the process chamber 201. As a result, since the substrates S stacked in the vertical direction can be uniformly processed, it is possible to improve a uniformity of the substrate processing on the surface of the substrate S and between the substrates S.

That is, it is possible to suppress an effect of the inert gas supplied to the heat insulating chamber 505 on the atmosphere of the process chamber 201. Even when the amount of the inert gas supplied to the heat insulating chamber 505 is increased, by suppressing the adhesion of reaction by-products by purging the heat insulating chamber 505 (which constitutes the heat insulating region B including the support 441) with the inert gas, it is possible to suppress the effect of the inert gas on the processing region A.

As the first gas, for example, a silicon (Si)-containing gas serving as the source gas may be used. As the silicon-containing gas, for example, a gas containing silicon and chlorine (Cl) (such as hexachlorodisilane (Si₂Cl₆, abbreviated as HCDS) gas) may be used.

### <Purge, Step S101>

In the present step, the valve 254 is closed to stop the supply of the first gas, and the valve 274 is opened to supply the inert gas serving as the purge gas into the gas supply pipe 271. When supplying the inert gas into the gas supply pipe 271, the valves 258, 275 and 268 may be opened to supply the inert gas serving as the purge gas into the gas supply pipes 255 and 265. In addition, with the valve 282 of the second exhaust pipe 281, the APC valve 283 and the valve 506 of the first exhaust pipe 504 open, the vacuum pump 284 vacuum-exhausts an atmosphere (inner atmosphere) of the reaction tube 210.

### <Second Gas Supply, Step S102>

After a predetermined time has elapsed from a start of the purge (step S102), the valve 268 is closed and the valve 264 is open to supply the second gas into the gas supply pipe 261. The second gas whose flow rate is adjusted by the MFC 263 is supplied into the reaction tube 210 from the gas supply structure 212 via the distribution structure 125, the nozzle 224 and the upstream side gas guide 214. Then, the second gas is exhausted through the space above the substrate S, the downstream side gas guide 215, the gas exhaust structure 213 and the second exhaust pipe 281. Further, when the second gas is being supplied, in order to prevent the second gas from entering the gas supply pipe 251, the valves 258 and 275 are opened so as to supply the inert gas through the nozzle 223.

In the present step, the second gas is supplied from beside the substrate S to the substrate S in the horizontal direction through the gas supply structure 212 (which is in communication with the inner portion of the reaction tube 210), and is exhausted through the second exhaust pipe 281.

In addition, in the present step, the valve 274 is opened, and the valve 506 is controlled to be fully open. The inert gas whose flow rate is adjusted by the MFC 273 is supplied into the heat insulating housing 510 via the gas supply pipe 271 and the inert gas flow passage 507. Further, the inert gas flows downward from the lower portion of the heat insulating housing 510 to the outside of the heat insulating housing 510, and is supplied to the upper surface of the base flange 401 and the inert gas flow passage 509. Then, the inert gas is exhausted through the first exhaust pipe 504 via the exhaust hole 503. For example, a supply amount of the inert gas in the present step is set to be 0.1 liter to 2.0 liters. That is, the supply amount of the inert gas in the present step is set to be greater than the supply amount of the inert gas supplied to the heat insulating region B in the first gas supply (step S100).

That is, in a state where the substrate S loaded into the process chamber 201 is heated, while the second gas is supplied to the processing region A for the substrate S, the valve 282 is opened to exhaust the gas through the second exhaust pipe 281. Further, in the present step, while the inert gas is supplied by the inert gas supplier 270 to the heat insulating chamber 505 (which constitutes the heat insulating region B below the processing region A), the valve 506 is opened to exhaust the gas through the first exhaust pipe 504. That is, the opening and closing operations of the valves 506 and 282 are controlled simultaneously. With such a configuration, by exhausting the atmosphere of the heat insulating region B (that is, the heat insulating chamber 505) through the first exhaust pipe 504, it is possible to suppress the adhesion of the reaction by-products to components arranged in the heat insulating region B such as the support 441 and the periphery of the valve 506.

Since the effect of the supply of the inert gas by the inert gas supplier 270 in the second gas supply is substantially the same as the effect of the supply of the inert gas by the inert gas supplier 270 in the first gas supply described above, descriptions thereof will be omitted.

As the second gas, for example, a gas serving as the reactive gas reacting with the first gas may be used. As the reactive gas, for example, a gas containing hydrogen (H) and nitrogen (N) (such as ammonia (NH₃), diazene (N₂H₂) gas, hydrazine (N₂H₄) gas and N₃H₈ gas) may be used.

In the present embodiments, the support 441 may be made of a metal component such as Hastelloy (nickel alloy). When the Hastelloy comes into contact with NH₃ at a high temperature and reacts, a surface of the support 441 turns black and nickel oxide is precipitated. The nickel oxide (which is precipitated) may affect surrounding components thereof. Further, when the surface of the support 441 turns black, opaque quartz may also turn black and accumulate the heat. As described above, by supplying the inert gas to the heat insulating chamber 505 by the inert gas supplier 270, it is possible to prevent the NH₃ from coming into contact with the support 441, and it is also possible to exhaust the metal component (which is precipitated from the support 441) to the outside of the process chamber 201.

### <Purge, Step S103>

After a predetermined time has elapsed from a supply of the second gas, the valve 264 is closed to stop the supply of the second gas. In the present step, the valve 274 is opened to supply the inert gas serving as the purge gas into the gas supply pipe 271. When supplying the inert gas into the gas supply pipe 271, the valves 258, 275 and 268 may be opened to supply the inert gas serving as the purge gas into the gas supply pipes 255 and 265. In addition, with the valve 282 of the second exhaust pipe 281, the APC valve 283 and the valve 506 of the first exhaust pipe 504 open, the vacuum pump 284 vacuum-exhausts the atmosphere of the reaction tube 210. Thereby, it is possible to suppress a reaction between the first gas and the second gas in gaseous states in the reaction tube 210.

### <Performing Predetermined Number of Times, Step S104>

A cycle (in which the steps S100 to S103 described above are sequentially and non-simultaneously performed in this order) is performed a predetermined number of times (n times, where n is an integer of 1 or more). As a result, it is possible to form a film of a predetermined thickness on the substrate S. In the present embodiments, for example, a silicon nitride (SiN) film is formed.

That is, in a state where the substrate S loaded into the process chamber 201 is heated, while alternately supplying the first gas and the second gas to the process chamber 201, the first gas, the second gas and the reaction by-products are exhausted through the second exhaust pipe 281 connected to the process chamber 201. When exhausting the first gas, the second gas and the reaction by-products, while supplying the inert gas to the heat insulating chamber 505 (which constitute the heat insulating region B disposed below the process chamber 201) from thereunder, the inert gas is exhausted through the first exhaust pipe 504 connected to a side surface of the heat insulating chamber 505 vertically between the inert gas supplier 270 and the process chamber 201.

### <S14>

Subsequently, a substrate unloading step S14 will be described. In the substrate unloading step S14, the substrate S processed as described above is transferred (unloaded) out of the transfer chamber 217 in the order reverse to that of the substrate loading step S11.

### <S15>

Subsequently, a determination step S15 will be described. In the present step, it is determined whether or not the processing of the substrate S described above (that is, the steps S11 to S14) has been performed a predetermined number of times. When it is determined that the processing has not been performed the predetermined number of times, the substrate loading step S11 is performed again to process a subsequent substrate S to be processed. When it is determined that the processing has been performed the predetermined number of times, the substrate processing is terminated.

While the present embodiments are described by way of an example in which the horizontal gas flow is formed, it is sufficient as long as a main flow of the gas is generally formed in the horizontal direction. Further, a gas flow may be diffused in the vertical direction as long as it does not affect a uniform processing of the plurality of substrates.

Further, in the above, various expressions such as “the same”, “equal”, “similar” and the like are used. However, it goes without saying that the expressions described above mean “substantially the same”.

### (3) Other Embodiments of Present Disclosure

While the technique of the present disclosure is described in detail by way of the embodiments mentioned above, the technique of the present disclosure is not limited thereto and may be modified in various ways without departing from the scope thereof.

For example, the embodiments mentioned above are described by way of an example in which the first exhaust pipe 504 through which the inert gas supplied to the heat insulating chamber 505 is exhausted is constituted by two pipes, that is, the pipes 504a and 504b. However, the technique of the present disclosure is not limited thereto. For example, the first exhaust pipe 504 may be constituted by a single pipe. Even in such a modified example, it is possible to obtain substantially the same effect as in the embodiments mentioned above, and it is also possible to reduce the number of pipes.

For example, the embodiments mentioned above are described by way of an example in which the film is formed by using the HCDS gas as the first gas and the NH₃ gas as the second gas in the film processing step S13. However, the technique of the present disclosure is not limited thereto.

For example, the embodiments mentioned above are described by way of an example in which the first gas and the second gas are alternately supplied to the process chamber 201 and the inert gas is supplied to the heat insulating chamber 505 in accordance with the process recipe in the film processing step S13. However, the technique of the present disclosure is not limited thereto. That is, the film may be processed by simultaneously supplying the first gas and the second gas to the process chamber 201 and supplying the inert gas to the heat insulating chamber 505.

For example, in a step of oxidizing the film by simultaneously supplying hydrogen (H₂) gas and oxygen (O₂) gas, since both of the H₂ gas and the O₂ gas are lighter than the N₂ gas, an effect of the inert gas is greater than that of the H₂ gas or the O₂ gas. Therefore, when the first exhaust pipe 504 is not present, the uniformity of the substrate processing between the substrates S may be significantly affected by the inert gas supplied to the heat insulating chamber 505. In other words, when the first gas and the second gas supplied to the process chamber 201 contain components lighter than the inert gas, by providing the first exhaust pipe 504 beside the heat insulating chamber 505, it is possible to reduce the effect of the inert gas supplied to the heat insulating chamber 505. As a result, it is possible to improve the uniformity of the substrate processing between the substrates S as compared with a case where the first exhaust pipe 504 is not present. In other words, even in such a modified example, it is possible to obtain substantially the same effect as in the embodiments mentioned above, and it is also possible to improve the uniformity of the substrate processing between the substrates S.

For example, even when the film is processed using the first gas or the second gas, or using the first gas and the second gas in a plasma state, it is possible to obtain substantially the same effect as in the embodiments mentioned above.

For example, the embodiments mentioned above are described by way of an example in which the first gas is supplied in the flash-like manner using the tank 259 in the first gas supply (step S100) in the film processing step S13. However, the technique of the present disclosure is not limited thereto. That is, the technique of the present disclosure can be preferably applied even when the first gas is supplied without using the flash-like manner. Even in such a modified example, it is possible to obtain substantially the same effect as in the embodiments mentioned above. Further, even in such a modified example (that is, when the first gas is supplied without using the flash-like manner), it is possible to reduce the supply amount of the inert gas supplied through the inert gas supplier 270 as compared with a case where the first gas is supplied in the flash-like manner. For example, the supply amount of the inert gas supplied through the inert gas supplier 270 may be set to be an amount within a range from 0.01 liter to 0.3 liter.

For example, the technique of the present disclosure can be preferably applied even when the second gas is supplied in the flash-like manner in the second gas supply (step S102) in the film processing step S13. Even in such a modified example, it is possible to obtain substantially the same effect as in the embodiments mentioned above.

For example, the embodiments mentioned above are described by way of an example in which the film forming process is performed as the substrate processing performed by the substrate processing apparatus 10. However, the technique of the present disclosure is not limited thereto. That is, instead of or in addition to the film forming process exemplified above, the technique of the present disclosure can be preferably applied even when film forming processes other than the film forming process exemplified above are performed.

For example, the embodiments mentioned above are described by way of an example in which a substrate processing apparatus including a hot wall type process furnace is used to form the film. However, the technique of the present disclosure is not limited thereto. For example, the technique of the present disclosure may be preferably applied when a substrate processing apparatus including a cold wall type process furnace is used to form the film.

The process procedures and the process conditions of each process using the substrate processing apparatuses exemplified above may be substantially the same as those of the embodiments or the modified examples mentioned above. Even in such a case, it is possible to obtain substantially the same effects as in the embodiments or the modified examples mentioned above.

Further, the embodiments or the modified examples mentioned above may be appropriately combined. The process procedures and the process conditions of each combination thereof may be substantially the same as those of the embodiments or the modified examples mentioned above.

According to some embodiments of the present disclosure, it is possible to improve the uniformity of the substrate processing.

What is claimed is:

1. A substrate processing apparatus comprising:
a process chamber in which a substrate is processed;
a process gas supplier capable of supplying a process gas to the process chamber;
a heater capable of heating the process chamber;
a heat insulating chamber constituting a heat insulating region provided below the process chamber;
an inert gas supplier capable of supplying an inert gas to the heat insulating chamber from thereunder;
a first exhauster provided with a first exhaust pipe connected to a side surface of the heat insulating chamber vertically between the inert gas supplier and the process chamber; and
a second exhauster provided with a second exhaust pipe connected to the process chamber.

2. The substrate processing apparatus of claim 1, wherein the process gas supplier is configured to supply the process gas from beside the substrate while the substrate is in the process chamber, and
wherein the second exhauster is configured to exhaust the process gas along a direction away from a location from which the process gas is supplied.

3. The substrate processing apparatus of claim 1, wherein the process chamber comprises:
a reaction tube into which the substrate is loaded;
a gas supply structure provided at a side of the reaction tube; and
a gas exhaust structure disposed opposite to the gas supply structure with the reaction tube interposed therebetween,
wherein the heat insulating chamber is provided below the process chamber, and
wherein the second exhaust pipe is connected to the gas exhaust structure.

4. The substrate processing apparatus of claim 1, wherein the substrate and one or more substrates are arranged in the vertical direction in the process chamber.

5. The substrate processing apparatus of claim 1, wherein the process chamber comprises:
a reaction tube in which the substrate and one or more substrates arranged in the vertical direction are processed;
a gas supply structure provided at a side of the reaction tube; and
a gas exhaust structure disposed opposite to the gas supply structure with the reaction tube interposed therebetween, and
wherein the gas exhaust structure comprises:
a first region provided adjacent to the process chamber; and
a second region provided below the first region.

6. The substrate processing apparatus of claim 1, wherein a diameter of the first exhaust pipe is set to be smaller than a diameter of the second exhaust pipe.

7. The substrate processing apparatus of claim 1, wherein a conductance of the first exhaust pipe is set to be smaller than a conductance of the second exhaust pipe.

8. The substrate processing apparatus of claim 1, wherein the first exhaust pipe is configured such that a diameter of an upstream portion of the first exhaust pipe is set to be larger than a diameter of a downstream portion of the first exhaust pipe.

9. The substrate processing apparatus of claim 7, further comprising
a controller configured to be capable of controlling a valve provided at the first exhaust pipe such that the valve is not fully closed while the process gas is being supplied to the process chamber.

10. The substrate processing apparatus of claim 1, wherein the first exhaust pipe is connected to the second exhaust pipe at a confluence portion of the second exhaust pipe.

11. The substrate processing apparatus of claim 10, further comprising
a valve provided downstream of the confluence portion.

12. The substrate processing apparatus of claim 1, further comprising
a controller configured to be capable of controlling a valve provided at the first exhaust pipe and a valve provided at the second exhaust pipe such that the valve provided at the first exhaust pipe and the valve provided at the second exhaust pipe are controlled to open and close simultaneously.

13. The substrate processing apparatus of claim 1, wherein the heater is provided beside the process chamber, and
the first exhaust pipe is provided below the heater.

14. The substrate processing apparatus of claim 13, wherein the substrate and one or more substrates are stacked and arranged in the process chamber, and
wherein the heater is provided adjacent to the substrate and the one or more substrates.

15. The substrate processing apparatus of claim 1, further comprising
a support containing a metal component and configured to support a substrate support,
wherein the first exhauster is capable of exhausting the metal component precipitated from the support.

16. The substrate processing apparatus of claim 1, wherein the process gas supplied to the process chamber contains a component lighter than the inert gas.

17. The substrate processing apparatus of claim 1, further comprising:
a memory configured to store process conditions for each type of substrate processing; and
a controller configured to be capable of setting a supply amount of the inert gas in accordance with the type of substrate processing stored in the memory.

18. A substrate processing method comprising:
(a) supplying a process gas into a process chamber while a substrate loaded into the process chamber is heated;
(b) supplying an inert gas into a heat insulating chamber from thereunder by an inert gas supplier, wherein the heat insulating chamber constitutes a heat insulating region provided below the process chamber;
(c) exhausting the process gas through a second exhaust pipe connected to the process chamber; and
(d) exhausting the inert gas through a first exhaust pipe connected to a side surface of the heat insulating chamber vertically between the inert gas supplier and the process chamber.

19. A method of manufacturing a semiconductor device, comprising
the method of claim 18.

20. A non-transitory computer-readable recording medium storing a program that causes a substrate processing apparatus, by a computer, to perform:
(a) supplying a process gas into a process chamber while a substrate loaded into the process chamber is heated;
(b) supplying an inert gas into a heat insulating chamber from thereunder by an inert gas supplier, wherein the heat insulating chamber constitutes a heat insulating region provided below the process chamber;
(c) exhausting the process gas through a second exhaust pipe connected to the process chamber; and
(d) exhausting the inert gas through a first exhaust pipe connected to a side surface of the heat insulating chamber vertically between the inert gas supplier and the process chamber.
